(19) United States
(12) Patent Application Publication
(10) Pub. No.: US 2025/0279313 A1
(43) Pub. Date: Sep. 4, 2025

(54) LID AND HYDBRID SUBSTRATE SUPPORT FOR EFFICIENT HEATING AND COOLING IN PROCESS CHAMBERS

(71) Applicant: Applied Materials, Inc., Santa Clara, CA (US)

(72) Inventors: Yogananda Sarode Vishwanath, Bangalore (IN); Anand Kumar, Bangalore (IN); Santosh Nesarkar, Santa Clara, CA (US); Imad Yousif, Santa Clara, CA (US); Harinath Reghunathanna, Santa Clara, CA (US); John Anthony O’Malley, III, Campbell, CA (US)

(21) Appl. No.: 18/595,231

(22) Filed: Mar. 4, 2024

(51) Int. Cl. H01L 21/687; H01J 37/32; H01L 21/683

(52) U.S. Cl. CPC H01L 21/68757; H01J 37/32495; H01J 37/32522; H01L 21/6833; H01J 2237/334

(57) ABSTRACT

A lid for a process chamber includes a first ceramic disc including a first dielectric material having a first thermal conductivity, a second ceramic disc including a second dielectric material having a second thermal conductivity, and a bond layer that bonds the second ceramic disc to the first ceramic disc. The first thermal conductivity may be greater than the second thermal conductivity.

### TECHNICAL FIELD

Some embodiments of the present disclosure relate, in general, to a hybrid lid and a hybrid substrate support for efficient heating and cooling in process chambers.

### BACKGROUND

Inductively coupled plasma (ICP) is used for etching substrates in semiconductor processes. ICP sources offer several advantages over other plasma sources, including a high plasma density under low working pressures, a controllable ion flux and energy, and a simple configuration. In order to maintain a high plasma density in the ICP. a very high radio frequency (RF) power is often delivered to the coils, which can heat the dielectric lid near the antenna to a high temperature, and cause cracks in the lid. Additionally, when the temperature difference across two points on the lid (also referred to as “temperature delta”) increases beyond a particular difference of (e.g., 15° C.) it may cause thermal stresses in the lid, which may cause the lid to crack and/or break. The probability of such failure increases exponentially beyond a certain temperature delta (e.g., 60° C.).

Additionally, ICP based chambers use increased source power handling capabilities (˜8 to 10 KW). However, existing dielectric lids are composed of alumina, which has low thermal conductivity and high specific heat. Due to low thermal conductivity, the heat transfer efficiency of the lid is low for both cooling and heating purposes. Low thermal conductivity results in high temperature drop across the lid thickness, and a high temperature drop across the thickness results in high thermal stresses, which can cause lids to crack. Additionally, high specific heat of alumina makes it inefficient for both heating and cooling purposes as it requires larger amount of heat to increase or decrease the temperature of lid.

### SUMMARY

Some embodiments of the present disclosure described herein cover a hybrid lid for a process chamber. The hybrid lid includes a first ceramic disc including a first dielectric material having a first thermal conductivity, a second ceramic disc including a second dielectric material having a second thermal conductivity, and a bond layer that bonds the second ceramic disc to the first ceramic disc. The first thermal conductivity may be greater than the second thermal conductivity.

Some embodiments of the present disclosure described herein cover a lid for a process chamber including a ceramic disc including aluminum nitride. The ceramic disc may further include a first ceramic disc including a first dielectric material having a first thermal conductivity, a second ceramic disc including a second dielectric material having a second thermal conductivity, and a bond layer that bonds the second ceramic disc to the first ceramic disc. The first thermal conductivity may be greater than the second thermal conductivity.

Some embodiments of the present disclosure described herein cover a hybrid substrate support including a top plate including a first dielectric material having a first thermal conductivity, a bottom plate including a second dielectric material having a second thermal conductivity, and a bond that bonds the top plate and the bottom plate. The first thermal conductivity may be greater than the second thermal conductivity.

Some embodiments of the present disclosure described herein cover a method including forming a first disc of a lid or a substrate support including a first dielectric material having a first thermal conductivity, forming a second disc of the lid or the substrate support including a second dielectric material having a second thermal conductivity, and bonding the first disc to the second disc. The first thermal conductivity may be greater than the second thermal conductivity.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional side view of one embodiment of a processing chamber;

FIG. 2 depicts a sectional side view of one embodiment of a substrate support in a process chamber;

FIGS. 3A-3B depict sectional side views of embodiments of a substrate support in a process chamber;

FIGS. 4A-4D depict sectional side views of embodiments of a hybrid lid of a process chamber;

FIGS. 5A-5B depict sectional side views of embodiments of a hybrid lid of a process chamber;

FIGS. 6A-6B depict sectional side views of embodiments of a hybrid lid of a process chamber;

FIG. 7 illustrates one embodiment of a method of forming a hybrid lid or a hybrid substrate support for a process chamber;

FIG. 8 depicts a sectional side view of an embodiment of a lid for a process chamber; and

FIGS. 9A-9B depict sectional side views of an embodiment of a hybrid lid of a process chamber.

### DETAILED DESCRIPTION OF EMBODIMENTS

Embodiments of the present disclosure provide a hybrid substrate support including two or more plates (also referred to as discs). One or more plates of those two or more plates may include one or more functional elements such as chucking electrodes, heating elements, radio frequency (RF) electrodes, zone heaters, pixelated heaters, gas channels, etc. The two or more plates may be bonded using diffusion bonding or metal bonding. Alternatively, a bonding material or an interface layer may be used to bond the two or more plates together. In some embodiments, the hybrid substrate support may include a top plate made of a first material and a bottom plate made of a second material. The first material may have a coefficient of thermal conductivity (simply referred to as thermal conductivity) that is greater than the second material. In some embodiments, the first material may include aluminum nitride, boron nitride, silicon carbide, beryllium oxide, sapphire, gallium nitride, zinc oxide, or a combination thereof. The second material may include aluminum oxide (also referred to as alumina) or yttrium oxide (also referred to as yttria), or a heat blocking ceramic.

The combination of two or more materials used for a hybrid substrate support provides the hybrid substrate support with the ability to withstand higher temperatures. In some embodiments, the top plate has a top portion having a first diameter and a bottom portion having a second diameter, which may be greater than the first diameter. In some embodiments, a bottom surface of the top plate includes a cavity having a third diameter that is less than the first diameter, and a top surface of the bottom plate includes a projection approximately having the third diameter that fits inside the cavity. In some embodiments, an outermost diameter of the bottom plate corresponds to the second diameter. In some embodiments, the bottom plate may include a plurality of holes and the top plate may include a plurality of projections that fit into the holes of the bottom plate.

Advantages of the hybrid substrate support include a high temperature and low voltage operation because the hybrid substrate support offers a strong chucking force and good thermal uniformity. Good thermal uniformity refers to the even distribution of temperature within a given material. A pure alumina substrate support may develop thermal stresses due to varying temperatures across the thickness or diameter of the substrate support. However, a hybrid substrate support including two or more dielectric materials can lower the thermal gradient, thus improving thermal uniformity across the substrate support. Other advantages include significant energy savings because the alumina in the bottom plate acts as a heat blocking material and so the top plate can reach the desired temperature with less heat input, thus enabling energy savings (e.g., 20% or more for a given loading condition). Furthermore, the substrate support interface between the electrostatic chuck and the cooling plate experiences lesser temperature (e.g., 50° C. lesser for a given load condition), which helps better manage the interface materials.

Embodiments of the present disclosure also provide a hybrid lid for a processing chamber. The hybrid lid may include a first ceramic disc including a first dielectric material having a first thermal conductivity, and a second ceramic disc including a second dielectric material having a second thermal conductivity, which may be lower than the first thermal conductivity. The first ceramic disc and the second ceramic disc may be bonded using diffusion bonding or metal bonding. Alternatively, a bonding material or an interface layer may be used to bond the two or more discs together. The bond layer may include at least one of flexible graphite, an organic elastomer, Al, In, Ni, Ti, or an alloy comprising Ni—Ti or Mo—Mg or Cu—Ag or Al alloy. In some embodiments, the first dielectric material may include aluminum nitride, boron nitride, silicon carbide, beryllium oxide, sapphire, gallium nitride, zinc oxide, or a combination thereof. The second dielectric material may include aluminum oxide (also referred to as alumina) or yttrium oxide, or a heat blocking ceramic. In some embodiments, the second dielectric material may be spray coated or deposited onto a bottom surface of the first ceramic disc. In some embodiments, the second dielectric material may have a plasma etch resistance that is greater than that of the first dielectric material.

In some embodiments, the first ceramic disc may include one or more functional elements such as concentric zone heaters. The concentric zone heaters may be individually controlled. Alternatively, the concentric zone heater can be controlled together. In some embodiments, the first ceramic disc forms a top of the lid and has a first diameter. The second ceramic disc forms a bottom of the lid and has a second diameter that is less than the first diameter. In some embodiments, the first ceramic disc forms a top of the lid and has a first diameter at a top of the first ceramic disc and a second diameter at a bottom of the first ceramic disc. The second diameter may be smaller than the first diameter, and the second ceramic disc may have the second diameter. In some embodiments, the second ceramic disc has a first diameter at a top and a second diameter at a bottom of the second ceramic disc that is smaller than the first diameter. The second ceramic disc may include a cavity formed within the top of the second ceramic disc, the cavity having a third diameter that is less than the second diameter. The first ceramic disc may have approximately the third diameter and may be positioned within the cavity. In some embodiments, a bottom surface of the first ceramic disc includes a plurality of concentric grooves, and a top surface of the second ceramic disc includes a plurality of concentric heat transfer fins that fit into the plurality of concentric grooves.

Embodiments of the present disclosure also provide a method for forming a hybrid lid or a substrate support. The method includes forming a first disc of a lid or a substrate support including a first dielectric material having a first thermal conductivity. The method further includes forming a second disc of the lid or the substrate support including a second dielectric material having a second thermal conductivity. The method further includes bonding the first disc to the second disc. In some embodiments, the first thermal conductivity may be greater than the second thermal conductivity.

Advantages of the disclosed embodiments include improved thermal stresses on the lid because the hybrid structure results in a lower thermal gradient as compared to a pure alumina lid. A pure alumina lid may develop thermal stresses due to varying temperatures across the lid. However, a hybrid lid including two or more dielectric materials can lower the thermal gradient, thus improving thermal uniformity across the lid. Additionally, the hybrid lid takes 30-40% lesser time to achieve the desired temperature with the same heat loading condition, thus improving thermal efficiency. Because one or more elements of the hybrid lid has a coefficient of thermal conductivity that is greater than alumina, the hybrid lid has better thermal conductivity when compared to a pure alumina lid. Furthermore, with improved thermal efficiency it takes lesser time for the hybrid lid to cool off during a cooling phase. This results in improved convective cooling of the lid when wafer processing is being carried out.

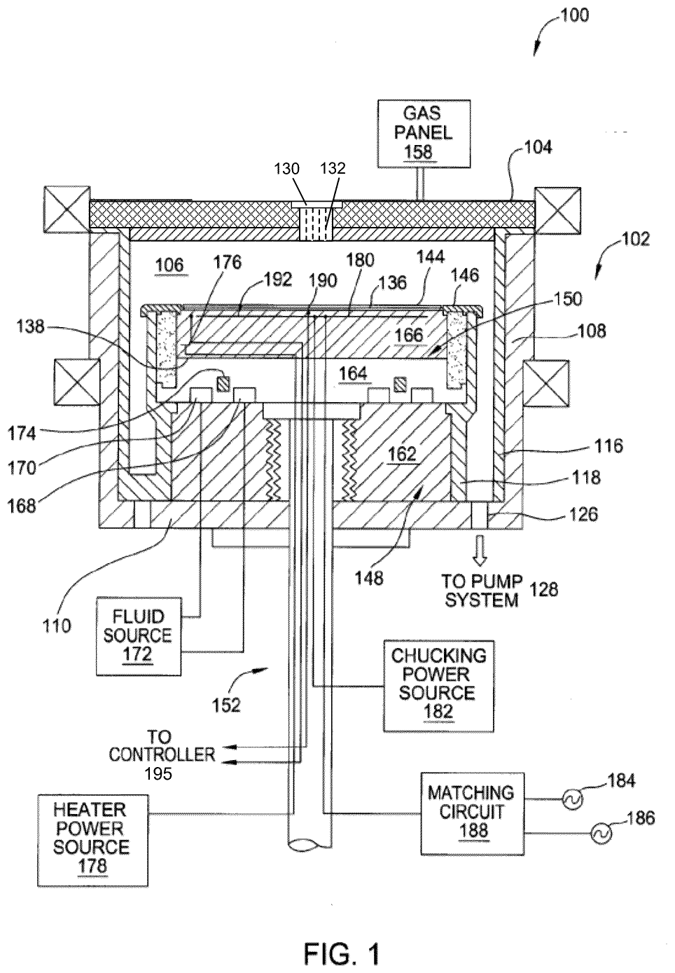

FIG. 1 is a sectional view of one embodiment of a processing chamber 100 having a substrate support 150 disposed therein. The processing chamber 100 may be any type of processing chamber, such as a deposition chamber, an etch chamber, an oxidation chamber, an implant chamber, and so on. While the substrate support 150 is described as being an electrostatic chuck assembly or a heater assembly in some embodiments, the substrate support may be replaced with other types of substrate support assemblies, such as a vacuum chuck assembly, a deposition heater assembly, and so on. In one embodiment, the substrate support 150 includes a puck assembly 166 having an upper puck plate bonded to a lower puck plate, as will be discussed in greater detail below. The substrate support 150 may additionally include more than two plates, where each plate may include zero or more different functional elements of the substrate support (e.g., chucking electrodes, radiofrequency (RF) electrodes, main heating electrodes, auxiliary heating electrodes, cooling channels, and so on). The puck assembly 166 can be coupled to a cooling plate by multiple fasteners, or by a bond such as a metal bond, an organic bond, a polymer bond, etc., or a combination thereof.

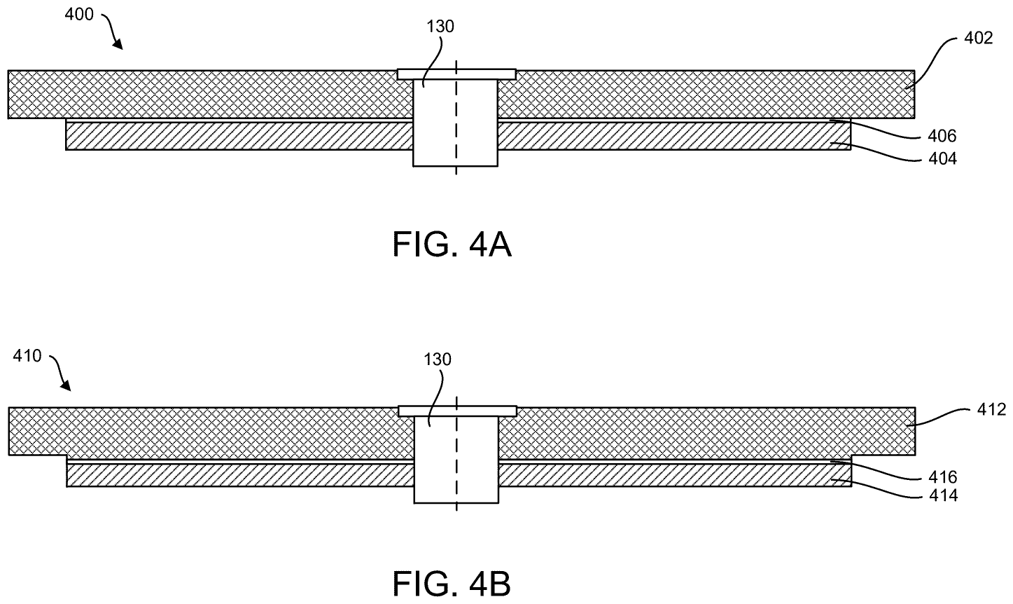

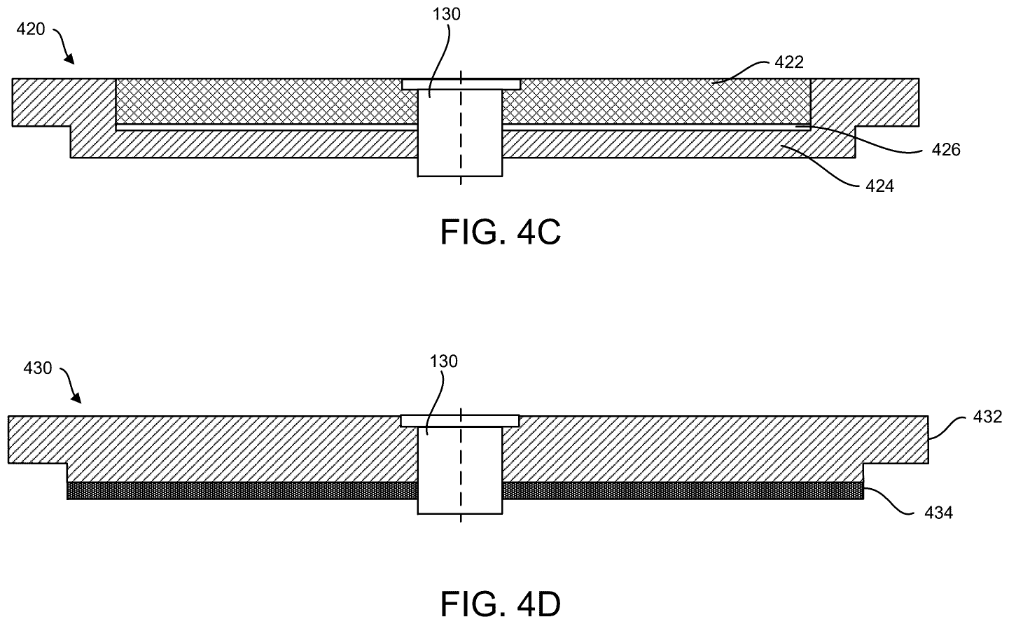

The processing chamber 100 includes a chamber body 102 and a lid 104 that enclose an interior volume 106. Different embodiments of lid 104 will be described in further detail with respect to FIGS. 4A-9B. The chamber body 102 may be fabricated from aluminum, stainless steel, or other suitable material. The chamber body 102 generally includes sidewalls 108 and a bottom 110. An outer liner 116 may be disposed adjacent the side walls 108 to protect the chamber body 102. The outer liner 116 may be fabricated and/or coated with a plasma or halogen-containing gas resistant material. In one embodiment, the outer liner 116 is fabricated from aluminum oxide. In another embodiment, the outer liner 116 is fabricated from or coated with yttria, yttrium alloy, or an oxide thereof.

An exhaust port 126 may be defined in the chamber body 102 and may couple the interior volume 106 to a pump system 128. The pump system 128 may include one or more pumps and throttle valves utilized to evacuate and regulate the pressure of the interior volume 106 of the processing chamber 100.

The lid 104 may be supported on the sidewall 108 of the chamber body 102. The lid 104 may be opened to allow access to the interior volume 106 of the processing chamber 100, and may provide a seal for the processing chamber 100 while closed. A gas panel 158 may be coupled to the processing chamber 100 to provide process and/or cleaning gases to the interior volume 106 through a gas distribution assembly 130 or nozzle that may be part of the lid 104. Examples of processing gases may be used to process in the processing chamber including halogen-containing gas, such as C₂F₆, SF₆, SiCl₄, HBr, NF₃, CF₄, CHF₃, CH₂F₃, Cl₂ and SiF₄, among others, and other gases such as O₂, or N₂O. Examples of carrier gases include N₂, He, Ar, and other gases inert to process gases (e.g., non-reactive gases). The gas distribution assembly 130 may have multiple apertures 132 on the downstream surface of the gas distribution assembly 130 to direct the gas flow to the surface of the substrate 144. Additionally, or alternatively, the gas distribution assembly 130 can have a center hole where gases are fed through a ceramic gas nozzle. The gas distribution assembly 130 may be fabricated and/or coated by a ceramic material, such as silicon carbide, Yttrium oxide, etc. to provide resistance to halogen-containing chemistries to prevent the gas distribution assembly 130 from corrosion.

In embodiments, the substrate support 150 is disposed in the interior volume 106 of the processing chamber 100 below the gas distribution assembly 130. The substrate support 150 holds a substrate 144 during processing. An inner liner 118 may be coated on the periphery of the substrate support 150. The inner liner 118 may be a halogen-containing gas resist material such as those discussed with reference to the outer liner 116. In one embodiment, the inner liner 118 may be fabricated from the same materials as the outer liner 116.

In one embodiment, the substrate support 150 is part of a greater assembly 148 that includes the substrate support 150 as well as a mounting plate 162 supporting a pedestal 152. In one embodiment, the substrate support 150 further includes a thermally conductive base referred to herein as a cooling plate 164 coupled to a puck assembly (also referred to as a puck plate assembly) 166. The cooling plate 164 may be coupled to the puck assembly 166 by multiple fasteners and/or by a bonding layer. The substrate support 150 described in embodiments may be used for Johnsen-Rahbek and/or Coulombic electrostatic chucking in embodiments. The substrate support 150 may additionally or alternatively be used as a heater, such as a deposition heater that is configured to heat a support substrate 144 during a deposition process.

In one embodiment, a protective ring 146 is disposed over a portion of the puck assembly 166 at an outer perimeter of the puck assembly 166. In one embodiment, the puck assembly 166 (or one or more plates of the puck assembly 166) is coated with a protective layer 136. Alternatively, the puck assembly 166 may not be coated by a protective layer 136. The protective layer 136 may be a ceramic such as Y₂O₃ (yttria or yttrium oxide), Y₄Al₂O₉ (YAM), Al₂O₃ (alumina), Y₃Al₅O₁₂ (YAG), YAlO3 (YAP), Quartz, SiC (silicon carbide), Si₃N₄ (silicon nitride) Sialon, AlN (aluminum nitride), AlON (aluminum oxynitride), TiO₂ (titania), ZrO₂ (zirconia), TiC (titanium carbide), ZrC (zirconium carbide), TiN (titanium nitride), TiCN (titanium carbon nitride), Y₂O₃ stabilized ZrO₂ (YSZ), and so on. The protective layer may also be a ceramic composite such as Y₃Al₅O₁₂ distributed in Al₂O₃ matrix, Y₂O₃—ZrO₂ solid solution or a SiC—Si₃N₄ solid solution. The protective layer may also be a ceramic composite that includes a yttrium oxide (also known as yttria and Y₂O₃) containing solid solution. For example, the protective layer may be a ceramic composite that is composed of a compound Y₄Al₂O₉ (YAM) and a solid solution Y₂-xZrₓO₃ (Y₂O₃—ZrO₂ solid solution). Note that pure yttrium oxide as well as yttrium oxide containing solid solutions may be doped with one or more of ZrO₂, Al₂O₃, SiO₂, B₂O₃, Er₂O₃, Nd₂O₃, Nb₂O₅, CeO₂, Sm₂O₃, Yb₂O₃, or other oxides. Also note that pure Aluminum Nitride as well as doped Aluminum Nitride with one or more of ZrO₂, Al₂O₃, SiO₂, B₂O₃, Er₂O₃, Nd₂O₃, Nb₂O₅, CeO₂, Sm₂O₃, Yb₂O₃, or other oxides may be used. Alternatively, the protective layer may be sapphire or MgAlON.

In embodiments, the puck assembly 166 includes an upper puck plate (not shown) and a lower puck plate (not shown) bonded by a metal and/or organic bond. The puck assembly 166 may also include more than two plates. The upper puck plate and/or one or more other plates may be formed from a monolithic dielectric or electrically insulative material (e.g., having an electrical resistivity of greater than 10¹⁴ Ohm·meter) that is usable for semiconductor processes at temperatures of 150° C. and above. In one embodiment, the upper puck plate and/or other plate(s) is composed of materials usable from about 20° C. to about 500° C. In one embodiment, the upper puck plate and/or other plate(s) is AlN or another ceramic, or boron nitride, silicon carbide, beryllium oxide, sapphire, gallium nitride, zinc oxide, or a combination thereof. The AlN upper puck plate and/or other plate(s) may be undoped or may be doped. For example, the AlN may be doped with Samarium oxide (Sm₂O₃), Cerium oxide (CeO₂), Titanium dioxide (TiO₂), or a transition metal oxide. In one embodiment, the lower puck plate and/or other plate(s) is Al₂O₃. The Al₂O₃ lower puck plate and/or other plate(s) may be undoped or may be doped. For example, the Al₂O₃ may be doped with Titanium dioxide (TiO₂) or a transition metal oxide. In some embodiments, each of the plates of the puck assembly 166 may be formed of a same ceramic. In other embodiments, different plates of the puck assembly 166 may be formed of different ceramics.

The lower puck plate and/or one or more other plates may have a coefficient of thermal expansion that is matched or close to a coefficient of thermal expansion of the upper puck plate. In one embodiment, the lower puck plate and/or other plate(s) is a SiC porous body that is infiltrated with an AlSi alloy (referred to as AlSiSiC). The lower puck plate and/or other plate(s) may alternatively be AlN or Al₂O₃ or other ceramic material or a combination thereof (e.g., aluminum oxynitride (ALON)). In one embodiment, the lower puck plate and/or other plate(s) is undoped AlN or undoped Al₂O₃. In one embodiment, the lower puck plate and/or other plate(s) is composed of the same material as the upper puck plate. The AlSiSiC material, AlN or Al₂O₃ may be used, for example, in reactive etch environments or in inert environments.

In one embodiment, the lower puck plate and/or other plate(s) is Molybdenum. Molybdenum may be used, for example, if the puck assembly 166 is to be used in an inert environment. Examples of inert environments include environments in which inert gases such as Ar, O2, N, etc. are flowed. Molybdenum may be used, for example, if the puck assembly 166 is to chuck a substrate for metal deposition. Molybdenum may also be used for the lower puck plate and/or other plate(s) for applications in a corrosive environment (e.g., etch applications). In such an embodiment, exposed surfaces of the lower puck plate and/or other plate(s) may be coated with a plasma resistant coating after the lower puck plate is bonded to the upper puck plate. The plasma coating may be performed via a plasma spray process. The plasma resistant coating may cover, for example, side walls of the lower puck plate and an exposed horizontal step of the lower puck plate. In one embodiment, the plasma resistant coating is Al₂O₃. Alternatively, the plasma resistant coating may be Y₂O₃ or a Y₂O₃ containing oxide. Alternatively, the plasma resistant coating may be any of the materials described with reference to protective layer 136.

The mounting plate 162 is coupled to the bottom 110 of the chamber body 102 and includes passages for routing utilities (e.g., fluids, power lines, sensor leads, etc.) to the cooling plate 164 and the puck assembly 166. The cooling plate 164 and/or puck assembly 166 may include one or more embedded heating elements 176, embedded thermal isolators 174, conduits 168, 170 to control a lateral temperature profile of the substrate support 148, and/or other functional elements. In embodiments, different functions of the puck assembly 166 may be divided across multiple plates. For example, one plate may include RF electrodes, one plate may include primary heating electrodes, one plate may include auxiliary heating electrodes, and so on. In some embodiments, multiple functions are provided by a single plate. For example, one plate of puck assembly 166 may include both RF electrodes and chucking electrodes. In one embodiment, a thermal gasket 138 and/or o-ring is disposed on at least a portion of the cooling plate 164.

The conduits 168, 170 may be fluidly coupled to a fluid source 172 that circulates a temperature regulating fluid through the conduits 168, 170. The embedded thermal isolators 174 may be disposed between the conduits 168, 170 in one embodiment. The embedded heating elements 176 are regulated by a heater power source 178. The embedded heating elements 176 may be included in one plate (e.g., top plate) of puck assembly 166. The conduits 168, 170 and embedded heating elements 176 may be utilized to control the temperature of the puck assembly 166, which may heat and/or cool the puck assembly 166 and a substrate (e.g., a wafer) being processed. In one embodiment, the puck assembly 166 includes two separate heating zones that can maintain distinct temperatures. In another embodiment, the puck assembly 166 includes four different heating zones that can maintain distinct temperatures. In other embodiments, the puck assembly 166 includes more than four heating zones (e.g., 8, 16, 32, 64, 128, 216, etc. pixelate heating zones). The temperature of the puck assembly 166 and the thermally conductive base 164 may be monitored using multiple temperature sensors 190, 192, which may be monitored using a controller 195. The temperature sensors 190, 192 may be included in one plate of puck assembly 166 and/or in multiple plates of the puck assembly 166, which may be a same plate or plates or different plate or plates from the plate(s) containing the heating elements 176.

The puck assembly 166 may further include multiple gas passages such as grooves, mesas, seal bands, and other surface features that may be formed in an upper surface of a topmost plate of the puck assembly 166. The gas passages may be fluidly coupled to a source of a heat transfer (or backside) gas, such as He via holes drilled in the plates of the puck assembly 166. In operation, the backside gas may be provided at controlled pressure into the gas passages to enhance the heat transfer between the puck assembly 166 and the substrate 144.

In one embodiment, the puck assembly 166 includes at least one clamping electrode 180 controlled by a chucking power source 182. The clamping electrode 180 may be included in one plate of puck assembly 166. The clamping electrode 180 (also referred to as a chucking electrode) may further be coupled to one or more RF power sources 184, 186 through a matching circuit 188 for maintaining a plasma formed from process and/or other gases within the processing chamber 100. In one embodiment, a different RF electrode or set of electrodes are connected to one or more RF power sources 184, 186 and used for maintaining a plasma. The RF electrode(s) may be included in one plate of puck assembly 166. The one or more RF power sources 184, 186 may be capable of producing an RF signal having a frequency from about 50 kHz to about 3 GHz and a power of up to about 10,000 Watts. In one embodiment, an RF signal is applied to the metal base, an alternating current (AC) is applied to the heater and a direct current (DC) is applied to the clamping electrode 180.

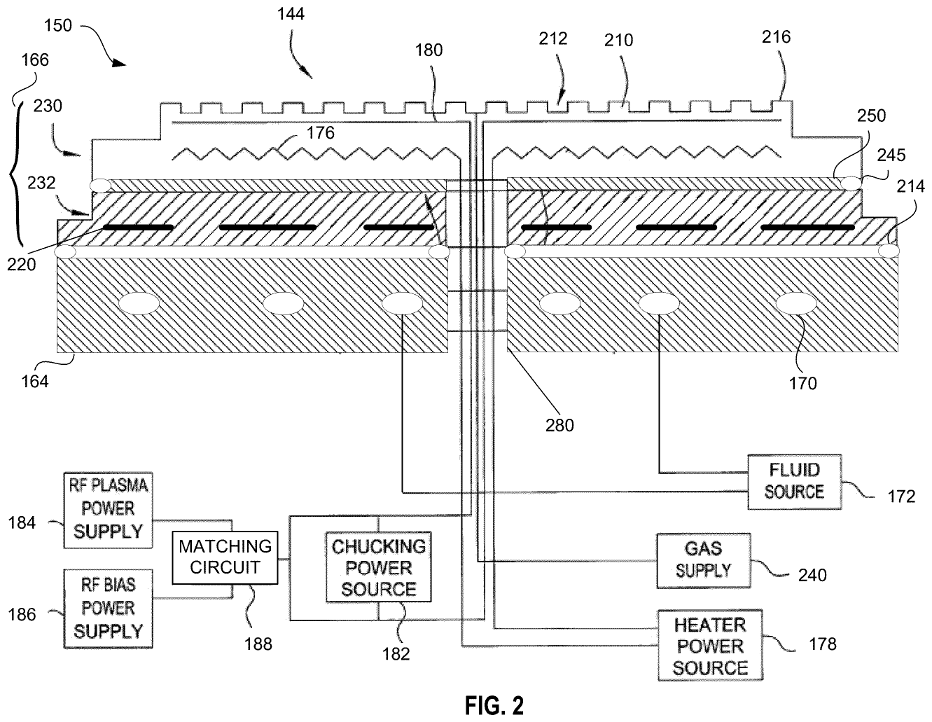

FIG. 2 depicts a cross-sectional view of one embodiment of the substrate support 150. The substrate support 150 includes the puck assembly 166 and the cooling plate 164 attached to the puck assembly 166. As shown, an o-ring 214 or gasket may be vulcanized to the cooling plate 164 along a perimeter of a top side of the cooling plate 164. Alternatively, the o-ring 214 or gasket may be disposed on the top side of the cooling plate 164 without being vulcanized thereto. Alternatively, no o-ring or gasket may be used at the interface of the cooling plate 164 and the puck assembly 166. Some embodiments are discussed herein with reference to o-rings and gaskets that are vulcanized to at least a portion of the cooling plate 164. However, it should be understood that the o-rings and/or gaskets may alternatively be vulcanized to the lower puck plate. Alternatively, the o-rings and/or gaskets may not be vulcanized to any surface. In one embodiment, the o-ring 214 or gasket is a perfluoropolymer (PFP) o-ring or polyimide o-ring or gasket. Alternatively, other types of high temperature o-rings may be used. In one embodiment, thermally insulating high temperature o-rings or gaskets are used. The o-ring 214 or gasket may be a stepped o-ring or gasket having a first step at a first thickness and a second step at a second thickness. This may facilitate uniform tightening of fasteners by causing the amount of force used to tighten the fasteners to increase dramatically after a set amount of compression of the o-ring 214 or gasket.

Additional o-rings (not shown) or gaskets may also be vulcanized to the top side of the cooling plate around a hole 280 at a center of the cooling plate 164 through which cables are run. Other smaller o-rings or gaskets may also be vulcanized to the cooling plate 164 around other openings, around lift pins, and so forth. For example, a gasket (e.g., a PFP gasket or polyimide gasket) may be vulcanized to the top side of the cooling plate 164. Examples of PFPs usable for the gasket or o-ring 214 are Dupont's™ ECCtreme™, Dupont's KALREZ® and Daikin's® DUPRA™. The o-ring 214 or gasket may provide a vacuum seal between a chamber interior volume and interior volumes within the substrate support 150. The interior volumes within the substrate support 150 may include open spaces within the pedestal 152 for routing conduits and wiring.

In one embodiment, the puck assembly 166 has a disc-like shape having an annular periphery that may substantially match the shape and size of the substrate 144 positioned thereon. An upper surface of the puck assembly 166 may have an outer ring 216, multiple mesas 210, and channels 212 between the mesas 210. In one embodiment, the puck assembly 166 includes an upper puck plate 230 bonded to the lower puck plate 232 by a metal bond, a ceramic bond, an organic bond, a polymer bond, or other type of bond. In one embodiment, the bond has different thermal conductivity in different directions. For example, the bond may have different thermal conductivity in the x, y and/or z directions. In some embodiments, the bond comprises a ceramic with metal fillers (e.g., having ellipsoid particles). The metal fillers may alter a thermal conductivity of the bond in a targeted direction. The thermal conductivity of the bond may accordingly be tailored in one or more directions or planes so that it has isotropic or anisotropic heat transfer properties. In one embodiment, the upper puck plate 230 may be fabricated by an electrically insulative ceramic material such as aluminum nitride (AlN), boron nitride, silicon carbide, beryllium oxide, sapphire, gallium nitride, zinc oxide, or a combination thereof. In one embodiment, the lower puck plate 232 may be fabricated by an electrically insulative ceramic material such as alumina (Al₂O₃), yttrium oxide, or a heat blocking ceramic.

In one embodiment, the material used for the lower puck plate 232 may be suitably chosen so that a coefficient of thermal expansion (CTE) for the lower puck plate 232 material substantially matches the CTE of the electrically insulative upper puck plate 230 material in order to minimize CTE mismatch and avoid thermo-mechanical stresses which may damage the puck 166 during thermal cycling. In one embodiment, the lower puck plate 232 is Molybdenum. In one embodiment, the lower puck plate 232 is alumina. In one embodiment, the lower puck plate 232 is AlN or Al₂O₃ or yttrium oxide, or a heat blocking ceramic. The lower puck plate may be composed of a different material as the upper puck plate, and may have a different purity level, a different grain size, different amounts of dopants, and so on to provide different material properties for the lower puck plate than the upper puck plate in embodiments.

The cooling plate 164 attached below the puck 166 may have a disc-like main portion and an annular flange extending outwardly from the main portion and positioned on the pedestal 152. In one embodiment, the cooling plate 164 may be fabricated by a metal, such as aluminum or stainless steel or other suitable materials. Alternatively, the cooling plate 164 may be fabricated by a composite ceramic, such as an aluminum-silicon alloy infiltrated SiC or Molybdenum to match a thermal expansion coefficient of the puck 166. The cooling plate 164 should provide good strength and durability as well as heat transfer properties.

In some embodiments, the upper puck plate 230 and the lower puck plate 232 are bonded together by a bond 250, which may be a metal bond, an organic bond, a polymer bond, a ceramic bond, or other type of bond. In one embodiment, diffusion bonding is used as a method of metal bonding plates of the substrate support 150 together. In one embodiment. the upper puck plate 230 and the lower puck plate 232 comprise materials which include aluminum (e.g., AlN or Al₂O₃). Bond 250 may be a metal or organic bond 250 that may include an “interlayer” of aluminum foil or other metal foil which is placed in a bonding region between the upper puck plate 230 and the lower puck plate 232. Pressure and heat may be applied to form a diffusion bond between the aluminum foil and the upper puck plate 230 and between the aluminum foil and lower puck plate 232. In another embodiment, the diffusion bond may be formed using other interlayer materials which are selected based upon the materials used for upper puck plate 230 and lower puck plate 232. In another embodiment, the upper puck plate 230 may be directly bonded to the lower puck plate 232 using direct diffusion bonding in which no interlayer is used to form the bond. An organic bond, ceramic bond, polymer bond, or other type of bond may also be formed to bond the plates together.

In one embodiment, an o-ring 245 is used to protect a metal or organic bond 250. In one embodiment, no o-ring 245 may be used if a diffusion bond is used to bond the upper puck plate and lower puck plate. A plasma resistant and high temperature o-ring 245 may be made of a perfluoropolymer (PFP) or polyimide in embodiments. The o-ring 245 may be a PFP with inorganic additives such as SiC in an embodiment. The o-ring 245 may be replaceable. When the o-ring 245 degrades it may be removed and a new o-ring may be stretched over the upper puck plate 230 and placed at a perimeter of the puck 166 at an interface between the upper puck plate 230 and the lower puck plate 232. The o-ring 245 may protect the metal or organic bond 250 from erosion by plasma. In some embodiments, no o-ring is used to protect the metal or organic bond 250.

The upper puck plate 230 includes mesas 210, channels 212, and an outer ring 216. In one embodiment, the upper puck plate 230 includes functional elements such as clamping electrodes 180 and/or one or more heating elements 176. Alternatively, the clamping electrodes 180 and/or heating elements 176 may be disposed in different plates (e.g., heating elements and/or clamping electrodes may be disposed in lower puck plate 232). In some embodiments, lower puck plate 232 may include one or more functional elements 220 (e.g., heating elements, clamping electrodes, and/or RF electrodes). The clamping electrodes 180 may be coupled to a chucking power source 182, and/or to an RF plasma power supply 184 and/or an RF bias power supply 186 via a matching circuit 188. The upper puck plate 230, lower puck plate 232 and/or other plates may additionally include gas delivery holes (not shown) through which a gas supply 240 pumps a backside gas such as He. Additionally, the upper puck plate 230, lower puck plate 232 and/or other plates may additionally include one or more cooling holes (not shown) for a cooling fluid to flow therethrough.

The upper puck plate 230 and/or lower puck plate 232 may have a thickness of about 1-25 mm or more. In one embodiment, the upper puck plate 230 has a thickness of about 3 mm. The clamping electrodes 180 may be located about 0.25 mm from an upper surface of the upper puck plate 230, and the heating elements 176 may be located about 1 mm under the clamping electrodes 180. The heating elements 176 may be screen printed heating elements having a thickness of about 10-200 microns in some embodiments. Alternatively, the heating elements may be resistive coils that use about 1-3 mm of thickness of the upper puck plate 230 in some embodiments. In such an embodiment, the upper puck plate 230 may have a minimum thickness of about 5 mm. In one embodiment, the lower puck plate 232 has a thickness of about 1-25 mm. In some embodiments, the upper and/or lower puck plates have thicknesses ranging from 1 mm to 10 mm, 2 mm to 8 mm, or other thicknesses. In embodiments, different puck plates may have the same or different thicknesses, which may range from 1-25 mm, for example. In embodiments, interface layers or bonding layers between puck plates may have a thickness of about 25 microns to about 1 mm (e.g., 1-14 mil).

The heating elements 176 may be electrically connected to a heater power source 178 for heating the upper puck plate 230. The upper puck plate 230 may include electrically insulative materials such as AlN. The lower puck plate 232 and upper puck plate 232 (and/or one or more other plates) may be made of the same materials and/or different materials. In one embodiment, the lower puck plate 232 is made of materials which are different from the materials used for the upper puck plate 230. The lower puck plate 232 is coupled to and in thermal communication with a cooling plate 164 having one or more conduits 170 (also referred to herein as cooling channels) in fluid communication with fluid source 172.

In one embodiment (not shown), the cooling plate 164 includes a base portion. In one embodiment, o-ring 214 may be vulcanized to the base portion. In one embodiment, the cooling plate 164 includes a spring loaded inner heat sink connected to the base portion by one or more springs. The springs apply a force to press the inner heat sink against the puck 166. A surface of the heat sink may have a predetermined roughness and/or surface features (e.g., mesas) that control heat transfer properties between the puck 166 and the heat sink. Additionally, the material of the heat sink may affect the heat transfer properties. For example, an aluminum heat sink will transfer heat better than a stainless steel heat sink. In one embodiment, the heat sink includes a grafoil layer on an upper surface of the heat sink.

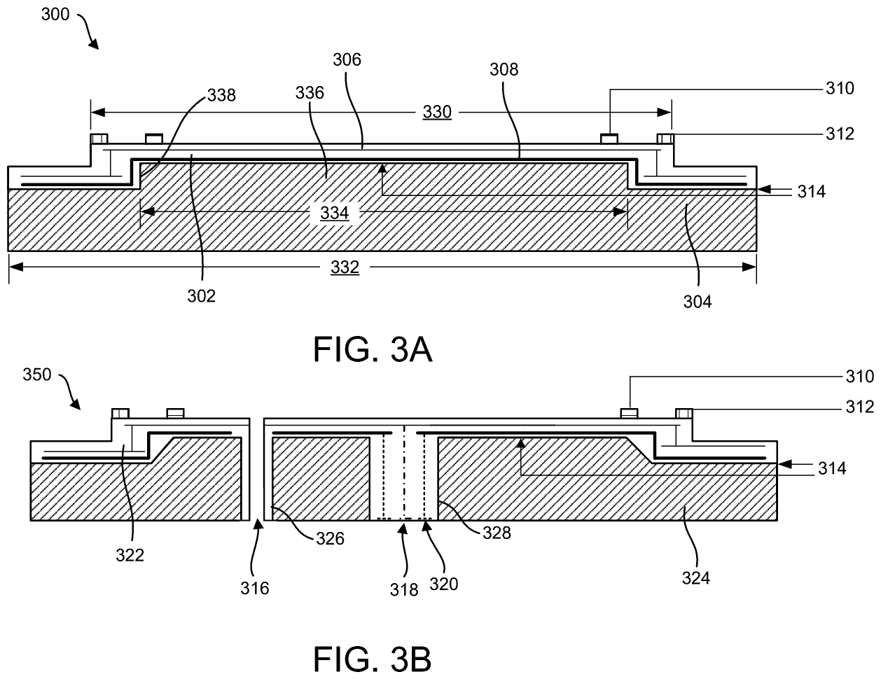

FIG. 3A depicts a sectional side view of one embodiment of a substrate support 300. Substrate support 300 may be used in process chamber 100, much like substrate support 150. The substrate support 300 includes a top plate 302 (also referred to as a disc) and a bottom plate 304. The top plate 302 may be made of a dielectric material such as aluminum nitride (AlN), boron nitride, silicon carbide, beryllium oxide, sapphire, gallium nitride, zinc oxide, or a combination thereof. The bottom plate 304 may include a dielectric material having a thermal conductivity that is less than the thermal conductivity of the top plate 302.

In some embodiments, the bottom plate 304 may include alumina (Al₂O₃) or yttrium oxide, or a heat blocking ceramic. The substrate support may further include a bond layer 314 that bonds the top plate 302 and the bottom plate 304. In some embodiments, the top plate 302 may be diffusion or metal bonded to the bottom plate 304. In some embodiments, the bond layer 314 may include materials such as graphite, an organic elastomer, Al, In, Ni, Ti, or an alloy including Ni—Ti or Mo—Mg or Cu—Ag or Al alloy.

The top plate 302 may include one or more functional elements such as a clamp electrode, a heating electrode, a zone heater, a pixelated heater, a radio frequency (RF) electrode, or a gas channel. In some embodiments, the top plate 302 may include one or more chucking electrodes 306 to electrostatically secure the substrate or wafer to the substrate support 300. In some embodiments, the top plate 302 may include one or more heating elements 308 to heat the top plate 302 to a desired temperature based on process being performed on the wafer or substrate. In some embodiments, the top plate 302 has a top portion having a first diameter 330 and a bottom portion having a second diameter 332. In some embodiments, the second diameter 332 is greater than the first diameter 330. In some embodiments, the second diameter 332 is lesser than the first diameter 330. The bottom surface of the top plate may further include a cavity 336 having a third diameter 334 that may be less than the first diameter 330. The top surface of the bottom plate 304 may further include a projection 338 approximately having the third diameter 332 that fits inside the cavity 336. In some embodiments, an outermost diameter of the bottom plate 304 corresponds to the second diameter 332. The bond layer 314 may be formed in such a way that it conforms to the top surface of the bottom plate 304. In some embodiments, bond layer 314 may cover an entire area of the top surface of the bottom plate 304. In some embodiments, bond layer 314 may cover only a portion of the top surface of the bottom plate 304.

The substrate support 300 may further include an inner seal band 310 and an outer seal band 312, which may be alternated with mesas (e.g., mesas 210) on a top surface of the top plate 302. Seal bands 310, 312 can be made from materials that are durable, chemically resistant, and able to withstand extreme conditions of semiconductor processing. In some embodiments, the seal bands 310, 312 can be made from materials such as elastomers, fluoropolymers, perfluoroelastomers (FFKM), silicone rubber, or Vitron®. The choice of material for the seal bands 310, 312 depends on the specific requirements of the process in the process chamber, including the chemicals used, the temperature range, the need for electrical insulation, and the vacuum level to be maintained. The material may be selected to ensure they do not outgas or leach contaminants that could compromise the process or the quality of the semiconductor being produced.

FIG. 3B depicts a sectional side view of one embodiment of a substrate support 350. The substrate support 350 includes a top plate 322 (also referred to as a disc) and a bottom plate 324. The top plate 322 may be made of a dielectric material such as aluminum nitride (AlN), boron nitride, silicon carbide, beryllium oxide, sapphire, gallium nitride, zinc oxide, or a combination thereof. The bottom plate 324 may include a dielectric material having a thermal conductivity that is less than the thermal conductivity of the top plate 322. In some embodiments, the bottom plate 324 may include alumina (Al₂O₃) or yttrium oxide, or a heat blocking ceramic. The substrate support may further include a bond layer 314 that bonds the top plate 322 and the bottom plate 324. In some embodiments, the top plate 322 may be diffusion or metal bonded to the bottom plate 324. In some embodiments, the bond layer 324 may include materials such as graphite, an organic elastomer, Al, In, Ni, Ti, or an alloy including Ni—Ti or Mo—Mg or Cu—Ag or Al alloy.

In the embodiment illustrated in FIG. 3B, the cavity 336 may have chamfered edges instead of sharp edges as illustrated in FIG. 3A. Similarly, the top portion of the bottom plate may have a projection 338 having a profile corresponding to and that fits inside the cavity in top plate 322. This may allow additional space in the top plate 322 to accommodate additional functional elements. Additionally, the bottom plate 324 may have a plurality of holes 326, 328, and the top plate 322 may include a plurality of projections that fit into the plurality of holes 326, 328. A central hole 328 may be used to route one or more terminal wires connecting the one or more functional elements to a power source connection or a ground connection. In some embodiments, the terminal wires may include a DC terminal 318 connecting the chucking electrode to a power source. In some embodiments, the terminal wires may include a heater terminal 320 connecting the heating element(s) to a power source. Through holes 316 may be used to house one or more lift pins that may be used to separate a wafer or substrate from the substrate support 350. In some embodiments, the lift pins may be made of sapphire, and can be raised to separate a wafer or substrate from the substrate support 350 and lowered to be housed in the holes 316 when not in use.

FIG. 4A depicts a sectional side view of an embodiment of a hybrid lid 400 of a process chamber. Hybrid lid 400 may be used in a process chamber 100, much like lid 104 in FIG. 1. Hybrid lid 400 may be used for enclosing a process area within the process chamber where one or more operations of a semiconductor manufacturing process may be carried out. Conventional lids are typically made of Al₂O₃ or alumina. In current process chambers, a combination of heating elements, axial fans for forced convection, and a set of baffles for flow direction are used to attain uniform temperature across the chamber lid. The temperature distribution on a lid's surface is dependent on these peripheral heating and cooling elements, and the thermal conductivity and geometry of the material forming the lid. For example, alumina has low thermal conductivity (e.g., about 25 w/mK), and so the temperature distribution of lids formed of alumina may not be uniform. Additionally, with higher source power (e.g., greater than 5 KW) to the process chamber, a temperature delta of greater than 50° C. can be observed on the surface of purely alumina lids. The temperature delta increases the stress at the center of the lid, and directly impacts the “safety factor” of the lid. The safety factor of a lid is directly dependent on the stresses it experiences and if the safety factor falls below a certain range (e.g., due to increased stresses), then the lid may be unsuitable for use in some processes because cracking or breakage may result from using lids below a certain safety factor.

Accordingly, in some embodiments the hybrid lid 400 includes a top ceramic disc 402 and a bottom ceramic disc 404. The top ceramic disc 402 may be made of a dielectric material such as aluminum nitride (AlN), boron nitride, silicon carbide, beryllium oxide, sapphire, gallium nitride, zinc oxide, or a combination thereof. The bottom ceramic disc 404 may include a dielectric material having a thermal conductivity that is less than the thermal conductivity of the top ceramic disc 402. In some embodiments, the bottom ceramic disc 404 may include alumina (Al₂O₃) or yttrium oxide, or a heat blocking ceramic. The top ceramic disc may face away from an interior of a process chamber, and the bottom ceramic disc may face towards the interior of the process chamber. The hybrid lid 400 may further include a bond layer 406 that bonds the top ceramic disc 402 and the bottom ceramic disc 404. In some embodiments, the top ceramic disc 402 may be diffusion or metal bonded to the bottom ceramic disc 404. In some embodiments, the bond layer 406 may include materials such as graphite, an organic elastomer, Al, In, Ni, Ti, or an alloy including Ni—Ti or Mo—Mg or Cu—Ag or Al alloy. In some embodiments, the hybrid lid 400 may include a gas distribution assembly 130 or nozzle to allow a fluid or gas to flow therethrough. In some embodiments, the dielectric material of the bottom ceramic disc 404 has a plasma etch resistance that is greater than the plasma etch resistance of the dielectric material of the top ceramic disc 402. This allows the bottom ceramic disc 404 to be exposed to higher plasma voltages and higher temperatures when the lid is closed. In the embodiment illustrated in FIG. 4A, the top ceramic disc 402 has a first diameter, and the bottom ceramic disc 404 has a second diameter that is less than the first diameter.

FIG. 4B depicts a sectional side view of an embodiment of a hybrid lid 410 of a process chamber. In this embodiment, ceramic disc 412 forms a top of the lid 410 and ceramic disc 414 forms a bottom of the lid 410. A bond layer 416 may bond the top ceramic disc 412 to the bottom ceramic disc 414. The top ceramic disc 412 has a first diameter at a top of the ceramic disc 412 and a second diameter at a bottom of the ceramic disc 412. In some embodiments, the second diameter is smaller than the first diameter. In some embodiments, the bottom ceramic disc 414 has the second diameter.

FIG. 4C depicts a sectional side view of an embodiment of a hybrid lid 420 of a process chamber. In this embodiment, ceramic disc 422 forms a portion of the top of the lid 420 and ceramic disc 424 forms a bottom of the lid 420. As shown here, the bottom ceramic disc 424 has a first diameter at a top of the ceramic disc and a second diameter at a bottom of the ceramic disc 424 that is smaller than the first diameter. The bottom ceramic disc 424 may include a cavity formed within the top surface. The cavity may have a third diameter that is less than the second diameter. In some embodiments, the top ceramic disc 422 may have approximately the third diameter and may be positioned within the cavity. A bond layer 426 may bond the top ceramic disc 412 to the bottom ceramic disc 414. In some embodiments, the top ceramic disc 422 and the bottom ceramic disc 424 may be diffusion or metal bonded.

FIG. 4D depicts a sectional side view of an embodiment of a hybrid lid 430 of a process chamber. In this embodiment, ceramic disc 432 forms a top of the lid 430. A bottom disc 434 of the lid 420 can be formed by spraying or depositing a ceramic material onto a bottom surface of the top disc 432. The top ceramic disc 432 may be made of a dielectric material such as aluminum nitride (AlN), boron nitride, silicon carbide, beryllium oxide, sapphire, gallium nitride, zinc oxide, or a combination thereof. The bottom ceramic disc 434 may include a dielectric material having a thermal conductivity that is less than the thermal conductivity of the top ceramic disc 432. In some embodiments, the bottom ceramic disc 434 may be formed by spraying or depositing alumina (Al₂O₃) or yttrium oxide on a bottom surface of the top disc 432.

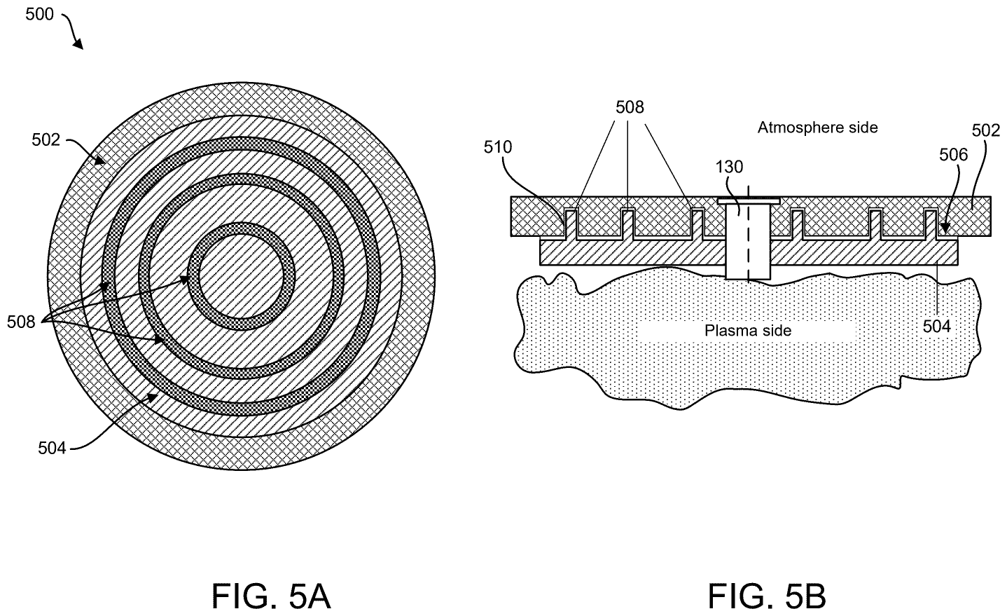

FIG. 5A depicts a top view of an embodiment of a hybrid lid 500 of a process chamber. FIG. 5B depicts a sectional view of the hybrid lid 500 illustrated in FIG. 5A. Hybrid lid 500 may be used in a process chamber 100, much like lid 104 in FIG. 1. The hybrid lid 500 includes a top ceramic disc 502 and a bottom ceramic disc 504. The top ceramic disc 502 may be made of a dielectric material such as aluminum nitride (AlN), boron nitride, silicon carbide, beryllium oxide, sapphire, gallium nitride, zinc oxide, or a combination thereof. The bottom ceramic disc 504 may include a dielectric material having a thermal conductivity that is less than the thermal conductivity of the top ceramic disc 502. In some embodiments, the bottom ceramic disc 504 may include alumina (Al₂O₃) or yttrium oxide, or a heat blocking ceramic. The hybrid lid 500 may further include a bond layer 506 that bonds the top ceramic disc 502 and the bottom ceramic disc 504. In some embodiments, the top ceramic disc 502 may be diffusion or metal bonded to the bottom ceramic disc 504. In some embodiments, the bond layer 506 may include materials such as graphite, an organic elastomer, Al, In, Ni, Ti, or an alloy including Ni—Ti or Mo—Mg or Cu—Ag or Al alloy. In some embodiments, the hybrid lid 500 may include a gas distribution assembly 130 or nozzle to allow a fluid or gas to flow therethrough. In some embodiments, the dielectric material of the bottom ceramic disc 504 has a plasma etch resistance that is greater than the plasma etch resistance of the dielectric material of the top ceramic disc 502. This allows the bottom ceramic disc 504 to be exposed to higher plasma voltages and higher temperatures when the lid is closed.

In some embodiments, a bottom surface of the top ceramic disc 502 includes a plurality of concentric grooves 510. A top surface of the bottom ceramic disc 504 includes a plurality of concentric heat transfer fins 508, which may be used to transfer heat away from the plasma side. The heat transfer fins 508 may be positioned such that areas with stronger plasma have higher heat transfer fins and areas with less strong plasma has lower heat transfer fins. The fins 508 may be made of the same material as the bottom disc 504. In some embodiments, the fins 508 may be made of a different material from the bottom disc 504. The grooves 510 may be formed such that each of the concentric heat transfer fins 508 fit into one of the of concentric grooves 510. The top disc 502 and bottom disc 504 may be diffusion bonded using high temperature and high pressure. The advantage of diffusion bonding includes the ability to create a high-strength bond without the need for adhesives or mechanical fasteners and generating minimal thermal and mechanical stress on the discs.

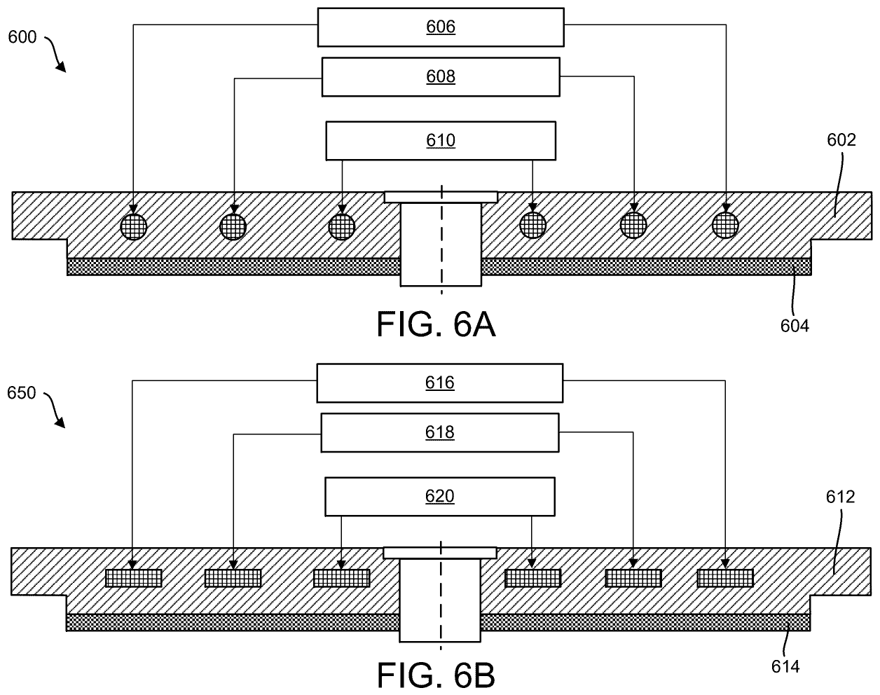

FIG. 6A depicts a sectional side view of an embodiment of a hybrid lid 600 of a process chamber. In this embodiment, ceramic disc 602 forms a top of the lid 600. A bottom disc 604 of the lid 600 can be formed by spraying or depositing a ceramic material onto a bottom surface of the top disc 602. The top ceramic disc 602 may be made of a dielectric material such as aluminum nitride (AlN), boron nitride, silicon carbide, beryllium oxide, sapphire, gallium nitride, zinc oxide, or a combination thereof. The bottom ceramic disc 604 may include a dielectric material having a thermal conductivity that is less than the thermal conductivity of the top ceramic disc 602. In some embodiments, the bottom ceramic disc 604 may be formed by spraying or depositing alumina (Al₂O₃) or yttrium oxide on a bottom surface of the top disc 602.

In some embodiments, the top ceramic disc 602 may include one or more functional elements such as a heating electrode, a zone heater, a pixelated heater, or a gas channel. In some embodiments, the one or more functional elements may include one or more concentric zone heaters, such as inner zone heater 610, mid-zone heater 608, and outer zone heater 606. Each of the heaters may operate at the same temperature or they may operate at different temperatures. For example, inner zone heater 610 may have a lower temperature than mid zone heater 608, which may have a lower temperature than outer zone heater 606. Alternatively, inner zone heater 610 may have a lower temperature than mid zone heater 608, which may have a higher temperature than outer zone heater 606, or combinations thereof. Each of the heaters 606-610 may be individually controlled by one or more controllers. Alternatively, each of the heaters 606-610 may be collectively controlled by single controller.

FIG. 6B depicts a sectional side view of an embodiment of a hybrid lid 650 of a process chamber. In this embodiment, ceramic disc 612 forms a top of the lid 650. A bottom disc 614 of the lid 650 can be formed by spraying or depositing a ceramic material onto a bottom surface of the top disc 612. The zone heaters 606-610 may be in the form of strips 616-620 instead of wires illustrated in FIG. 6A. Each of the heaters 616-620 may be individually controlled by one or more controllers. Alternatively, each of the heaters 616-620 may be collectively controlled by single controller.

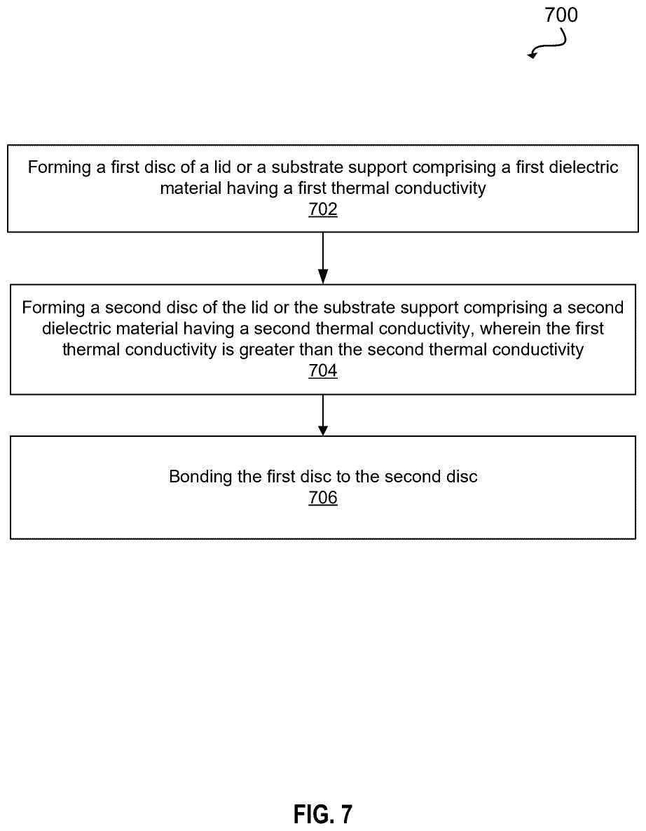

FIG. 7 illustrates one embodiment of a method 700 of forming a hybrid lid (e.g., hybrid lid 104, 400, 410, 420, 430, 500, 600, 650) or a hybrid substrate support (e.g., hybrid substrate support 150, 300, 350) for a process chamber (e.g., process chamber 100). At block 702, the method includes forming a first disc of a lid (e.g., disc 402, 412, 422, 432, 502, 602, 612) or a substrate support (e.g., 230, 302, 322) from a dielectric material such as aluminum nitride (AlN), boron nitride, silicon carbide, beryllium oxide, sapphire, gallium nitride, zinc oxide, or a combination thereof. At block 704, the method includes forming a second disc of the lid (e.g., disc 404, 414, 424, 434, 504, 604, 614) or the substrate support (e.g., 232, 304, 324) from a dielectric material having a thermal conductivity that is lesser than that of the first disc. In some embodiments, the second disc may be made of alumina or yttria, or a heat blocking ceramic.

At block 706, the first disc and the second disc are bonded together by a bond, which may be a metal bond, an organic bond, a polymer bond, a ceramic bond, or other type of bond. In one embodiment, diffusion bonding is used as a method of metal bonding plates (or discs) of the substrate support together. The bond may be a metal or organic bond that may include an “interlayer” of aluminum foil or other metal foil which is placed in a bonding region between the upper disc and the lower disc. Pressure and heat may be applied to form a diffusion bond between the aluminum foil and the upper disc and between the aluminum foil and lower disc. In another embodiment, the diffusion bond may be formed using other interlayer materials which are selected based upon the materials used for upper disc and lower disc. In another embodiment, the upper disc may be directly bonded to the lower disc using direct diffusion bonding in which no interlayer is used to form the bond. An organic bond, ceramic bond, polymer bond, or other type of bond may also be formed to bond the plates together.

It can be challenging to form large AlN sintered ceramic parts due to a large amount of shrinkage that occurs in the sintering process for AlN. For example, sintering an AlN green body into a solid sintered ceramic body of AlN can cause the body to shrink by approximately 20%. This can make it difficult to achieve target tolerances when machining the AlN top plate prior to sintering. Accordingly, in some embodiments the AlN top plate of the hybrid lid is composed of multiple sectional pieces. In some embodiments, the AlN top plate is divided into four equally sized sectional pieces. In some embodiments, the AlN top plate is divided into two, three, four, five, six, seven or eight sectional pieces, which may have the same or different sizes. While a sectionalized top plate is described with reference to AlN, the sectionalized top plate may also be formed of any of the other materials discussed herein with reference to the top plate.

Each sectional piece of the sectionalized top plate may be smaller than a single monolithic single body top plate, and so may be easier and cheaper to manufacture. Each sectional piece of the AlN top plate may be a pie shaped piece in embodiments. The bottom plate may be a single monolithic plate. Each of the sectional pieces of the AlN top plate may be bonded to the bottom plate using any of the bonding techniques discussed herein. In some embodiments, the sectional pieces are not bonded to one another. Heat generally flows radially from a center of the lid to a perimeter of the lid. Accordingly, failure to bond the sectional pieces to one another may not negatively impact heat transfer properties of the sectional pieces. In some embodiments, the sectional pieces are bonded together.

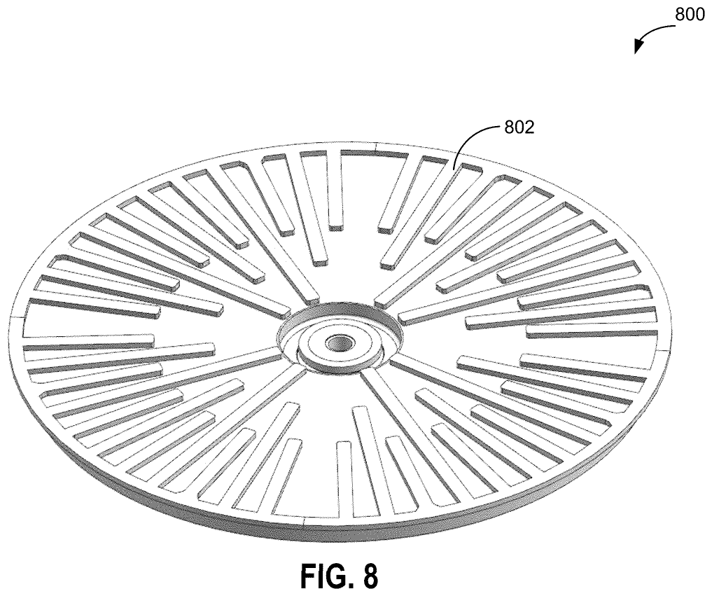

FIG. 8 illustrates a cross-sectional view of a portion of a chamber lid 800, according to some embodiments. The chamber lid 800 may be made entirely from a single dielectric material. In some embodiments, the chamber lid 800 may be made entirely from AlN or aluminum nitride. Chamber lid 800 may have diameter of about 12-30 inches, or more. In some embodiments, the chamber lid 800 may have a diameter of about 26.2 inches.

Chamber lid 800 may have a thickness of about 1-2 inches, or more. In some embodiments, the chamber lid 800 may have a thickness of about 1.01 inches. Chamber lid 800 may be used to cover the process chamber for a plasma process, and may be exposed to vacuum on the plasma side (e.g., inner surface) and to ambient environment on the outer surface. In some embodiments, one or both surfaces of the chamber lid 800 may be coated (e.g., spray coated) with alumina or another dielectric material. Chamber lid 800 may include one or more heating elements 802, which may be disposed in the lid or on the outer surface for providing uniform heating across the chamber lid 800.

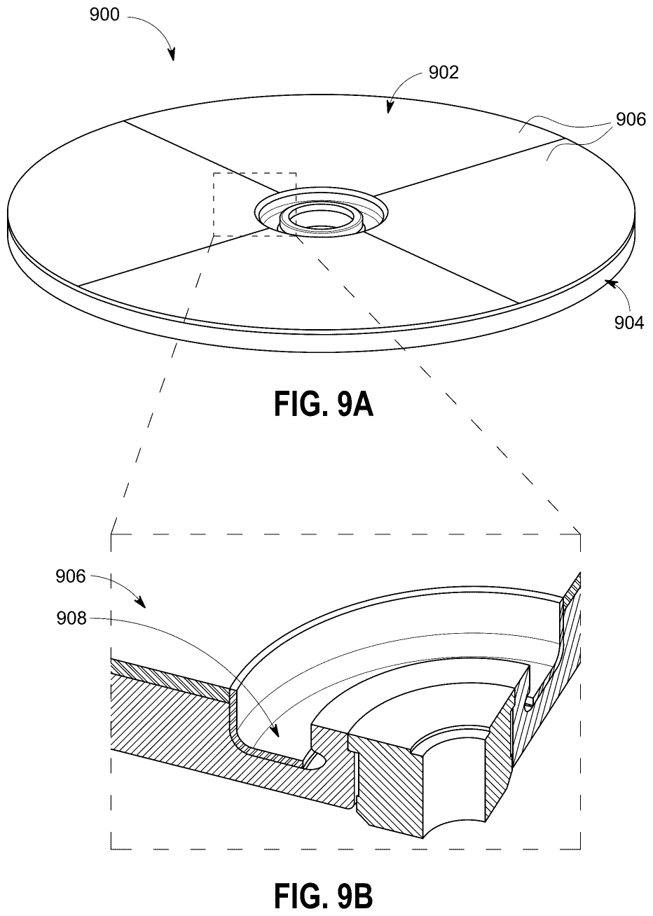

FIG. 9A illustrates an isometric view of a hybrid lid 900, according to some embodiments. Hybrid lid 900 may be used to cover the process chamber for a plasma process. Hybrid lid 900 may be exposed to vacuum on the plasma side (e.g., inner surface) and ambient environment on the outer surface. Hybrid lid 900 may include two or more ceramic discs 902, 904 (e.g., a top disc and a bottom disc) that may be bonded using a bonding material. In some embodiments, ceramic discs 902, 904 may not be bonded together.

Ceramic disc 904 may be made from a dielectric material such as alumina, which has lower thermal conductivity, and ceramic disc 902 may be made from a dielectric material such as aluminum nitride, which has a thermal conductivity greater than that of alumina. In some embodiments, the thermal conductivity of the aluminum nitride used may be about 50 w/mK or greater. In some embodiments, the thermal conductivity of the aluminum nitride used may be about 75 w/mK or greater. In some embodiments, the thermal conductivity of the aluminum nitride used may be 100 w/mK or greater. In some embodiments, the thermal conductivity of the aluminum nitride used may be 150 w/mK or greater. Hybrid lid 900 may have diameter of about 12-30 inches, or more. In some embodiments, the hybrid lid 900 may have a diameter of about 26.2 inches. Hybrid lid 900 may have a thickness of about 1-2 inches, or more. In some embodiments, the hybrid lid 900 may have a thickness of about 1.21 inches. In some embodiments, a ratio of the thickness of the ceramic disc 902 to the thickness of ceramic disc 904 may be about 20-100%. In some embodiments, the thickness of the aluminum nitride disc may be about 5 mm, or greater. In some embodiments, the thickness of the alumina disc may be about 1.01 inches, or greater.

In some embodiments, top ceramic disc 902 may be composed of two or more sections 906. Although only four sections or quadrants are illustrated in FIG. 3A, ceramic disc 902 may include more than four sections 906. In some embodiments, top ceramic disc 902 may include two sections 906. In some embodiments, top ceramic disc 902 may include three sections 906. In some embodiments, top ceramic disc 902 may include four sections 906. In some embodiments, top ceramic disc 902 may include eight sections 906. In some embodiments, top ceramic disc 902 may include ten or more sections 906. Each of the sections 906 may be attached to the plate 904 using a bonding material, such as graphite, a ceramic such as AlN, an organic elastomer or an epoxy material. In some embodiments, the bonding material may include flexible graphite, an organic elastomer, Al, In, Ni, Ti, AlN, or an alloy comprising Ni—Ti or Mo—Mg or Cu—Ag or Al alloy. Alternatively, or in addition, each of the sections 906 may be attached to the adjacent sections 906 using aluminum nitride. FIG. 9B illustrates a cross-sectional view of a portion of the hybrid lid 900 illustrated in FIG. 9A. Hybrid lid 900 may include a central neck portion 908 where a separate piece of aluminum nitride (or other material having sufficiently high thermal conductivity) may be attached to the bottom lid 904. The neck portion 908 may be an inner ring that is proximate to a center of the plate 902. In this neck portion 908, a ratio of a thickness of the aluminum nitride to a thickness of the alumina in the bottom disc may be 10% or greater. In some embodiments, the thickness of the neck portion 908 may be about 2 mm, or greater. In some embodiments, neck portion 908 may be thinner than sections 906. For example, sections 906 may have a thickness of about XX and neck portion 908 may have a thickness of about Y.

The neck portion 908 may be a ring having a U-shaped or L-shaped cross section in embodiments. The neck portion 908 may include a side wall that is taller than a thickness of the sections 906. In embodiments, the plate 904 may have a ring-shaped recess that is configured to receive the neck portion 908. When the neck portion 908 is seated in the ring-shaped recess, a side wall of the neck portion 908 may be flush with an upper surface of the sections 906.

In embodiments, neck portion 908 is a single ring-shaped piece that is coaxial with plate 904. A bottom surface of neck portion 908 may be bonded to plate 904, an outer side wall of neck portion 908 may be bonded to plate 904, and/or the outer side wall of neck portion 908 may be bonded to each of the sections 906. The bond between the neck portion 908 and sections 906 may be provided to ensure thermal contact and heat transfer from the neck portion 908 to the sections 906 in embodiments.

In some embodiments, ceramic discs 902, 904 may have the same diameter. In some embodiments, ceramic discs 902, 904 may have different diameters. For example, ceramic disc 902 may have a diameter that is greater than the diameter of ceramic disc 904. In some embodiments, ceramic disc 902 may have a diameter that is lesser than the diameter of ceramic disc 904. In some embodiments, the bonding material may include flexible graphite, an organic elastomer, Al, In, Ni, Ti, or an alloy comprising Ni—Ti or Mo—Mg or Cu—Ag or Al alloy, or an epoxy resin.

Advantages of the hybrid lid include improvement in safety factor of the lid by distributing the temperature more evenly across the surface of the lid. In embodiments where only aluminum nitride is used, aluminum nitride has a higher thermal conductivity when compared to alumina, and so the temperature delta between two points on the surface of the lid is significantly reduced. In embodiments where both aluminum nitride and alumina are used, the bottom disc ensures a tight enclosure for providing an inert environment and the top disc provides even distribution of the temperature across the surface of the lid, thereby resulting in lower temperature deltas and a high safety factor for the overall lid.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner. In one embodiment, multiple metal bonding operations are performed as a single step.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A lid for a process chamber, the lid comprising:
a first ceramic disc comprising a first dielectric material having a first thermal conductivity;
a second ceramic disc comprising a second dielectric material having a second thermal conductivity, wherein the first thermal conductivity is greater than the second thermal conductivity; and
a bond layer that bonds the second ceramic disc to the first ceramic disc.

2. The lid of claim 1, wherein the first dielectric material comprises at least one of aluminum nitride, boron nitride, silicon carbide, beryllium oxide, sapphire, gallium nitride, zinc oxide, or combinations thereof, and the second dielectric material comprises aluminum oxide.

3. The lid of claim 1, wherein the first ceramic disc comprises one or more functional elements comprising at least one of a heating electrode, a zone heater, a pixelated heater, or a gas channel.

4. The lid of claim 3, wherein the one or more functional elements comprise one or more concentric zone heaters, wherein the one or more concentric zone heaters are individually controlled.

5. The lid of claim 1, wherein the first dielectric material has a first plasma etch resistance, wherein the second dielectric material has a second plasma etch resistance, and wherein the second plasma etch resistance is greater than the first plasma etch resistance.

6. The lid of claim 1, wherein the bond layer comprises at least one of flexible graphite, an organic elastomer, Al, In, Ni, Ti, or an alloy comprising Ni—Ti or Mo—Mg or Cu—Ag or Al alloy.

7. The lid of claim 1, wherein the first ceramic disc forms a top of the lid and has a first diameter, and wherein the second ceramic disc forms a bottom of the lid and has a second diameter that is less than the first diameter.

8. The lid of claim 1, wherein the first ceramic disc forms a top of the lid and has a first diameter at a top of the first ceramic disc and a second diameter at a bottom of the first ceramic disc, wherein the second diameter is smaller than the first diameter and wherein the second ceramic disc has the second diameter.

9. The lid of claim 1, wherein:
the second ceramic disc has a first diameter at a top of the second ceramic disc and a second diameter at a bottom of the second ceramic disc that is smaller than the first diameter;
the second ceramic disc comprises a cavity formed within the top of the second ceramic disc, the cavity having a third diameter that is less than the second diameter; and
the first ceramic disc has approximately the third diameter and is positioned within the cavity.

10. The lid of claim 1, wherein:
a bottom surface of the first ceramic disc comprises a plurality of concentric grooves; and
a top surface of the second ceramic disc comprises a plurality of concentric heat transfer fins, wherein each of the plurality of concentric heat transfer fins fits into one of the plurality of concentric grooves.

11. The lid of claim 1, wherein the first ceramic disc comprises a plurality of pie-shaped sections.

12. The lid of claim 11, wherein the first ceramic disc further comprises a ring shaped section bonded to the plurality of pie-shaped sections at an inner diameter of the plurality of pie-shaped sections.

13. A substrate support, comprising:
a top plate comprising a first dielectric material having a first thermal conductivity;
a bottom plate comprising a second dielectric material having a second thermal conductivity, wherein the first thermal conductivity is greater than the second thermal conductivity; and
a bond that bonds the top plate and the bottom plate.

14. The substrate support of claim 13, wherein the first dielectric material comprises aluminum nitride, boron nitride, silicon carbide, beryllium oxide, sapphire, gallium nitride, zinc oxide, or combinations thereof and the second dielectric material comprises aluminum oxide.

15. The substrate support of claim 13, wherein the top plate comprises one or more functional elements comprising at least one of a clamp electrode, a heating electrode, a zone heater, a pixelated heater, a radio frequency (RF) electrode, or a gas channel.

16. The substrate support of claim 15, wherein the one or more functional elements comprise one or more concentric zone heaters, wherein the one or more concentric zone heaters are individually controlled.

17. The substrate support of claim 15, further comprising:
one or more terminal wires connecting the one or more functional elements to at least one of a power source connection or a ground connection.

18. The substrate support of claim 13, wherein the bond comprises at least one of flexible graphite, an organic elastomer, Al, In, Ni, Ti, or an alloy comprising Ni—Ti or Mo—Mg or Cu—Ag or Al alloy.

19. The substrate support of claim 13, wherein the top plate has a top portion having a first diameter and a bottom portion having a second diameter, wherein the second diameter is greater than the first diameter.

20. The substrate support of claim 19, wherein:
a bottom surface of the top plate comprises a cavity having a third diameter that is less than the first diameter;
a top surface of the bottom plate comprises a projection approximately having the third diameter that fits inside the cavity; and
an outermost diameter of the bottom plate corresponds to the second diameter.

21. The substrate support of claim 13, wherein:
the bottom plate comprises a plurality of holes; and
the top plate comprises a plurality of projections that fit into the plurality of holes.

22. A method comprising:
forming a first disc of a lid or a substrate support comprising a first dielectric material having a first thermal conductivity;
forming a second disc of the lid or the substrate support comprising a second dielectric material having a second thermal conductivity, wherein the first thermal conductivity is greater than the second thermal conductivity; and
bonding the first disc to the second disc.
